(19) United States
(12) Patent Application Publication
(10) Pub. No.: US 2015/0090433 A1
(43) Pub. Date: Apr. 2, 2015

(54) THERMAL SHIELD SHEET

(71) Applicant: 3M INNOVATIVE PROPERTIES COMPANY, ST. Paul, MN (US)

(72) Inventor: Kentaro Tamura, Kanagawa (JP)

(21) Appl. No.: 14/391,207

(22) PCT Filed: Apr. 19, 2013
(86) PCT No.: PCT/US2013/037339

§ 371 Date: Oct. 8, 2014

(30) Foreign Application Priority Data
Apr. 19, 2012 (JP) 2012-095741

(51) Int. Cl. H05K 7/20; F28F 3/02

(52) U.S. Cl. CPC H05K 7/2039; F28F 3/02
USPC 165/185

(57) ABSTRACT

A method of reducing heat in an electronic device includes providing a housing, providing a heat generating component and positioning a heat reduction sheet between the housing and the heat generating component. The heat reduction sheet includes a substrate, a first porous layer and a second porous layer. Each of the substrate and first and second porous layers has a first main surface and a second main surface. The first porous layer has an average cavity diameter of between approximately 0.01 μm and approximately 10 μm. The second porous layer has an average cavity diameter of between approximately 0.01 μm and approximately 10 μm. At least a portion of the first main surface of the substrate is in contact with at least part of the first main surface of the first porous layer. At least a portion of the second main surface of the substrate is in contact with at least part of the first main surface of the second porous layer.

### FIELD OF THE INVENTION

The present invention relates to a heat reduction sheet and an electronic device including a heat reduction sheet.

### BACKGROUND

Various kinds of heat reduction sheets are known. For example, Patent Document 1 discloses a thermal insulation sheet having a base material layer, a heat retention resin layer, and a shift prevention layer. Patent Document 2 discloses a sheet material having a waterproof diaphragm, a protective covering layer, and a radiant heat interception layer. Further, Patent Document 3 discloses a porous sheet made by irradiating ultraviolet rays onto a resin composition. There are cases wherein if a conventional heat reduction sheet has a thickness of less than 0.5 mm for example, then the heat reduction characteristics and tensile strength need to be improved further. Particularly in cases in which it used for the heat reduction sheet inside of electronic devices, it is important to have excellent heat reduction characteristics and tensile strength even when it is thin. As a pre-filter material sheet, Patent Document 4 (US2001-0017280A) discloses reinforced three zone microporous membranes and Patent Document 5 (U.S. Pat. No. 4,707,265) discloses reinforced microporous membranes.

### SUMMARY

In one embodiment, the present invention is a method of reducing heat in an electronic device. The method includes providing a housing, providing a heat generating component and positioning a heat reduction sheet between the housing and the heat generating component. The heat reduction sheet of includes a substrate, a first porous layer and a second porous layer. The substrate has a first and second main surface. The first porous layer has a first and second main surface and an average cavity diameter of between approximately 0.01 μm and approximately 10 μm. The second porous layer has a first and second main surface and an average cavity diameter of between approximately 0.01 μm and approximately 10 μm. At least a portion of the first main surface of the substrate is in contact with at least part of the first main surface of the first porous layer. At least a portion of the second main surface of the substrate is in contact with at least part of the first main surface of the second porous layer.

In another embodiment, the present invention is a heat reduction sheet including at least one porous layer with a cavity diameter of between approximately 0.01 μm and approximately 10 μm, wherein the heat reduction sheet has an average porosity of between approximately 40% and approximately 95%, a tensile strength of more than approximately 4.0 MPa and a thickness of less than approximately 0.5 mm.

In another embodiment, the present invention is an electronic device including a housing, an electronic component creating heat and a heat reduction sheet provided between the housing and electronic component creating heat. The heat reduction sheet includes a substrate having a first main surface and a second main surface, a first porous layer having a first main surface and a second main surface, and a second porous layer having a first main surface and a second main surface. At least a portion of the first main surface of the substrate is in contact with at least part of the first main surface of the first porous layer and at least a portion of the second main surface of the substrate is in contact with at least part of the first main surface of the second porous layer.

In yet another embodiment, the present invention is an electronic device including a housing, an electronic component creating heat and a heat reduction sheet provided between the housing and electronic component creating heat. The heat reduction sheet includes at least one porous layer with a cavity diameter of between approximately 0.01 μm and approximately 10 μm. The heat reduction sheet has an average porosity of between approximately 40% and approximately 95%, a tensile strength of more than approximately 4.0 MPa and a thickness of less than approximately 0.5 mm.

### BRIEF DESCRIPTION OF THE DRAWINGS

FIG. 1 is a schematic cross-sectional view showing one embodiment of the heat reduction sheet of the present invention.

FIG. 2 is a diagrammatical view showing an example of the manufacturing method and a device for manufacturing the heat reduction sheet of this embodiment.

FIG. 3 is a partial diagrammatic sectional view showing one embodiment of the electronic device of the present invention.

FIG. 4 is a partial diagrammatic sectional view showing another embodiment of the electronic device of the present invention.

FIG. 5 is a partial diagrammatic sectional view showing yet another embodiment of the electronic device of the present invention.

FIG. 6 is a sectional electron micrograph of the heat reduction sheet manufactured in Embodiment 6.

### DETAILED DESCRIPTION

The heat reduction sheet of the present invention has excellent heat reduction characteristics and tensile strength, even when the sheet is thin, and is suitable for use inside an electronic device. The heat reduction sheet according to a first aspect of the present invention includes a substrate having a first and a second main surface; a first porous layer having a first and a second main surface and an average cavity diameter of between approximately 0.01 μm and approximately 10 μm; and a second porous layer having a first and a second main surface and an average cavity diameter of between approximately 0.01 μm and approximately 10 μm. At least a portion of the first main surface of the substrate is in contact with at least part of the first main surface of the first porous layer, and at least a portion of the second main surface of the substrate is in contact with at least part of the first main surface of the second porous layer.

In one embodiment, the first porous layer and the second porous layer are formed to obtain permeable structures of each layer.

In one embodiment, the thickness of the heat reduction sheet is less than approximately 0.5 mm.

In one embodiment, the substrate includes a non-woven fabric having an area of between approximately 5 g/m² and approximately 70 g/m².

The heat reduction sheet according to a second aspect of the present invention includes an average porosity of between approximately 40% and approximately 95%, a tensile strength of more than approximately 4.0 MPa, and a thickness of less than approximately 0.5 mm. The heat reduction sheet has at least one porous layer wherein the average cavity diameter is between approximately 0.01 μm and approximately 10 μm.

In one embodiment, the heat reduction sheet can have a compressibility of between approximately 40% and approximately 95%.

A third aspect of the present invention is an electronic device including a housing, at least one heating electronic component, and a heat reduction sheet provided between the housing and the at least one heating electronic component.

According to a fourth aspect of the present invention, the electronic device includes a housing, at least one heating electronic component, and a heat reduction sheet provided between the housing and the at least one heating electronic component. The heat reduction sheet includes a substrate having a first main surface and a second main surface, a first porous layer having a first main surface and a second main surface, and a second porous layer having a first main surface and a second main surface. At least a portion of the first main surface of the substrate is in contact with at least part of the first main surface of the first porous layer. At least a portion of the second main surface of the substrate is in contact with at least part of the first main surface of the second porous layer.

Hereinafter, the embodiments of the present invention will be described in detail while referencing the accompanying drawings. Note that, like reference numerals designate like parts throughout the figures thereof, and their descriptions have been omitted.

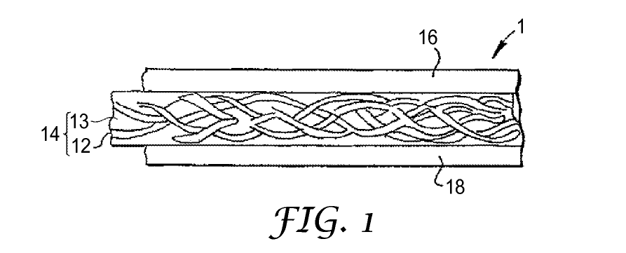

FIG. 1 is a schematic cross-sectional view showing one embodiment of the heat reduction sheet of the present invention. The heat reduction sheet 1 shown in FIG. 1 has a configuration with a first porous layer 16 and a second porous layer 18 placed on both sides of the substrate 14. The substrate 14 includes of a resin 13 and a maintenance body 12 embedded in the resin 13.

The first porous layer 16 and the second porous layer 18 each have an average cavity diameter of more than approximately 0.01 μm and less than approximately 10 μm. In particular, the average cavity diameter in the first porous layer 16 and the second porous layer 18 is than approximately 0.05 μm and less than approximately 5 μm, and more particularly more than approximately 0.1 μm and less than approximately 8 μm. In addition, the size of the average cavity diameter of the second porous layer for the average cavity diameter of the first porous layer 16 can be, for example, 3 to 15 times larger. Particularly, the aperture size distribution of the first porous layer 16 and the second porous layer 18 are narrow.

Even if the air of the cavity department is warmed when the heat reduction sheet has been heated, the convection in the cavity can be suppressed as much as possible by making the porous layer have a cavity of such a size. The maximum use of the insulation performance of the air in the cavity can be made by suppressing the convection. When the average cavity diameter is larger than approximately 10.0 μm, the heat reduction characteristics are insufficient to make a heat transfer due to the convection of the air in the cavity. When the average cavity diameter is smaller than approximately 0.01 μm, the heat reduction characteristics are insufficient for heat conduction due to the resin frame. Furthermore, to include a porous layer means making a substantially small three-dimensional frame structure such as the one shown in FIG. 6, and it allows it to be flexible in mechanical properties of the porous-layer-forming material. According to the theory formula described in the Plastic Form Handbook (Daily publication industrial newspaper page 29-65, 1997) on the mechanical properties of the foaming plastic, for example, in the case of a heat reduction sheet having a porosity of 40%, the compression coefficient of the elasticity becomes approximately 45% of the value of the non-cavity resin simple substance. In the case of a porosity of approximately 90%, the compression coefficient of elasticity is lowered to approximately 7% when it is the resin simple substance. In other words, when stress such as bending or pulling has been added to the porous layer (heat reduction sheet), the stress can be dispersed accordingly.

Note that the words “average cavity diameter” in the specification should be understood to mean the “average flow aperture” appropriately decided by the tests of ASTM-F316-70 and/or ASTM-F316-70.

The first porous layer 16 and second porous layer 18 can be manufactured from a resin material having a coefficient of elasticity that is more than approximately 0.01 GPa and less than approximately 20 GPa. Polyamides such as aramid or the nylon, polyimide, cellulose resin, polyester, polyolefin, rayon, polyethylene, polypropylene, polyvinylidene fluoride, polyether sulfone, phenolic resin, and acrylic acid resin and an active carbon are given as specific examples of such resin materials, and nylon is particularly included therein. Note that the word “nylon” includes a film for forming a co-polymer and a polyamide resin including a terpolymer. A circulation amidogen and a mixture of a different polyamide resin are included in the polyamide resin.

Generally, various kinds of nylons or polyamide resins are a co-polymer of all diamine and dicarboxylic acid, or a homopolymer of lactam and amino acid, however, the degree of crystallization, solid structure, melting point, and other properties of these differ greatly. Suitable nylons are a co-polymer of hexamethylene diamine and adipic acid (nylon 66), a co-polymer of hexamethylene diamine and veratrine acid (nylon 610), a poly caprolactam homopolymer (nylon 6), and a co-polymer of tetra methylene diamine and adipic acid (nylon 46). The ratio between the methylene (CH₂) and the amide (NHCO) base of the polyamide resin is in the range of about 4:1 to about 8:1. The nylon polymer can be used in a wide grade, and changes from approximately 15,000 (average molecular weight) to 42,000 for molecular weight or changes in other characteristics.

The very favorable kind of unit for constituting a polymer chain is polyhexamethylene adipamide, in other words, it is the nylon 66, and has a molecular weight of approximately 30,000. The polymer without the additive is generally suitable, however an antioxidant, a surface-active agent, and a charge-reforming agent, or the addition of a similar additive, is useful under certain conditions.

The maintenance body 12 is embedded in the substrate 14 to provide structural strength to the heat reduction sheet 1. The maintenance body 12 is prepared from an appropriate material using an appropriate method. The maintenance body 12 can be a porous body such as, for example, a non-woven fabric, cloth, or a web material. A non-woven fabric can be formed from methods such as extrusion or lamination extrusion. A cloth can be in a shape such as a grid or a mesh. The maintenance body 12 can include a non-woven fabric such as polyester, polypropylene, polyethylene, polyamide, polyimide, polyvinylidene fluoride, cellulose, or polyolefin. The maintenance body 12 can be formed from a fiber with enough strength and uniformity, should lie dispersed uniformly in a cross web pattern and the mechanical direction, and should be thin to bring about a high structural concentration degree and drop the low pressure.

The area of the non-woven fabric should be more than approximately 5 g/m² and less than approximately 70 g/m², and more particularly should be more than approximately 20 g/m² and less than approximately 40 g/m². The average line diameter of the non-woven fabric should be more than approximately 5 μm and less than approximately 200 μm, and more particularly should be more than approximately 15 μm and less than 150 μm. If the average line diameter is less than 5 μm, the desired tensile strength is not sufficient and the handling characteristics worsen.

If the average line diameter is larger than 200 μm, it is inappropriate as a thin heat reduction sheet because the thickness of the whole heat reduction sheet thickens. In addition, the thickness of the non-woven fabric should particularly be more than approximately 10 μm and less than approximately 250 μm.

A material similar to the materials constituting the first porous layer 16 and the second porous layer 18 described above can be given as the material constituting the resin 13. The materials which constitute resin 13 may be the same or different from the material constituting the first porous layer 16 and second porous layer 18 described above. The resin 13 should be unified to form the first porous layer 16 and second porous layer 18 by a manufacturing method to be mentioned later.

The substrate 14, the first porous layer 16 and the second porous layer 18 should be formed as a permeable structure. The substrate 14, the first porous layer 16 and the second porous layer 18 can also be formed as consecutive porous bodies. The substrate 14, the first porous layer 16 and the second porous layer 18 may be formed as the permeable structure to the second main surface of the second porous layer 18 from the second main surface of the first porous layer 16.

By at least having the substrate 14, the first porous layer 16 and the second porous layer 18 formed as consecutive porous bodies, damage to the film caused by stress of the cavity compressed with regards to bending and warping is eliminated, and more flexibility is added. For example, when heat reduction sheets are used in electronics, there are cases where they are compressed and used for small spaces, or cases where they come in contact with an electronic component having a corner, and the cavity is damaged in usages such as these, but the porous body itself does not get damaged.

The thickness of the first porous layer 16 and the second porous layer 18 can be changed independently of each other or they can be made to have substantially the same thickness. Having substantially the same thickness means that the thicknesses are within approximately 25% of the other.

The substrate 14 can have, for example, a larger average cavity diameter of more than approximately 20% than that of the average cavity diameter of at least one from either the first porous layer 16 or the second porous layer 18.

The substrate 14 should be as thin as possible as long as it still has sufficient structural strength. The thickness of the substrate 14 should be more than approximately 10 μm and less than approximately 250 μm, particularly more than approximately 50 μm and less than approximately 150 μm, and more particularly more than approximately 75 μm and less than approximately 100 μm. The thickness of the first porous layer 16 and the second porous layer 18 should be more than approximately 25 μm and less than approximately 250 μm, and particularly more than approximately 35 μm and less than approximately 150 μm. The thickness of the whole heat reduction sheet 1 should be no more than approximately 0.5 mm so as to be capable of being inserted in the gap between the electronic component and the housing. When a non-woven fabric is used as the maintenance body 12, the fiber of the non-woven fabric should not protrude out from the first porous layer 16 or the second porous layer 18. Note that this thickness can be adjusted by regulating the pressure impregnation condition in the manufacturing method to be mentioned later.

One embodiment of the heat reduction sheet of the present invention was described above; however, the heat reduction sheet of the present invention does not always have to be formed as three layers as described above.

In other words, the heat reduction sheet of the present invention has an average porosity of more than approximately 40% and less than approximately 95%, a tensile strength of more than approximately 4.0 MPa, and a thickness of less than approximately 0.5 mm, and a heat reduction sheet having at least one layer, wherein such layer may have a porous layer with an average cavity diameter of more than approximately 0.01 μm and less than approximately 10 μm. If the heat reduction sheet satisfies this matter, then the number of layers is not limited and may be, for example, a 1-layer or a 2-layer heat reduction sheet. For example, an example of a 1-layer heat reduction sheet is given in the above-described heat reduction sheet 1, wherein one from either the substrate 14, and the first porous layer 16 or the second porous layer 18 is excluded. In addition, an example of a 2-layer heat reduction sheet is given in the above-described heat reduction sheet 1, where one from either the first porous layer 16 or the second porous layer 18 is excluded.

The average porosity of the heat reduction sheet should be more than approximately 40% and less than approximately 90%. For example, when taking into consideration when a cavity with an average cavity diameter of 10 μm has an average porosity of 40%, the average thickness of the mesh of the porous layer formation resin materials is calculated as approximately 11 μm. On the other hand, when taking into consideration when a cavity with an average cavity diameter of 0.01 μm has an average porosity of 90%, the average thickness of the mesh of the porous layer formation resin materials is calculated as approximately 0.008 μm. In the heat transfer of the porous body, the heat transfer of the resin that has a higher thermal conductivity than the cavity part is carried out with precedence. Therefore, by making the thickness of the resin mesh that forms the porous body thinner, the heat conduction is suppressed, and the mechanical strength can be obtained by having a constant thickness. The average porosity and average cavity diameter are balanced with high mechanical strength and high heat reduction characteristics in the porous body. The tensile strength should be more than approximately 4.0 MPa.

The upper limit of the tensile strength is not particularly limited, but can be set to, for example, approximately 300 MPa. The lower limit of the thickness is also not particularly limited, but it can be set to, for example, more than approximately 0.01 mm. Note that, in the heat reduction sheet described above, the substrate 14, the first porous layer 16 and the second porous layer 18 may have independent air bubbles.

### Method for Manufacturing the Heat Reduction Sheet

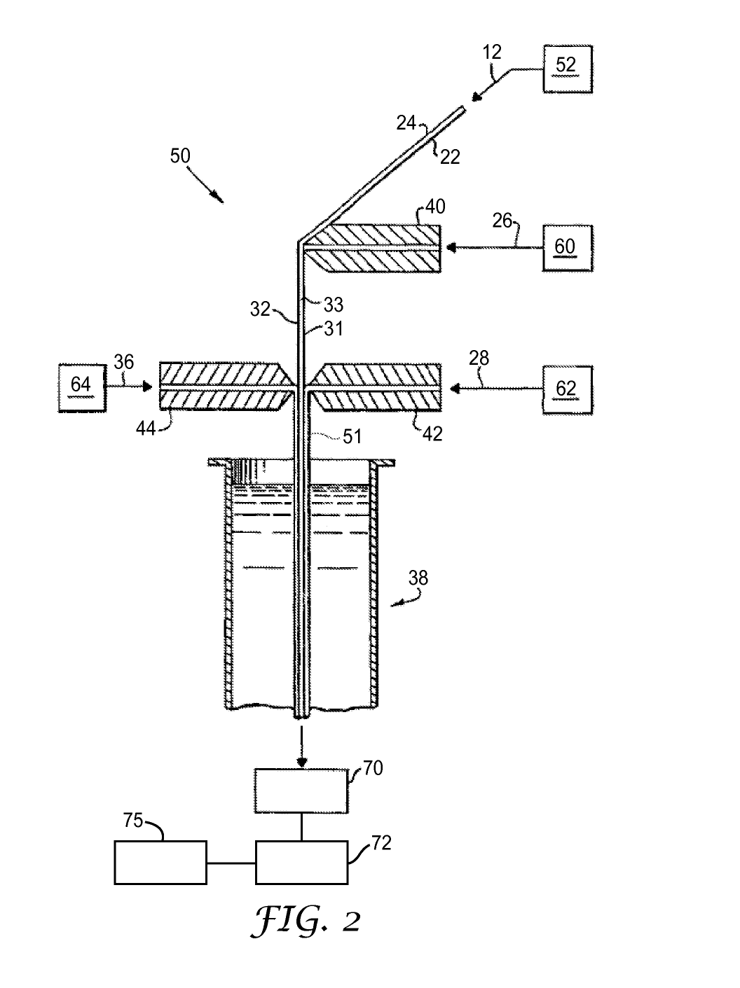

FIG. 2 is a diagrammatical view showing an example of the manufacturing method and a device for manufacturing the heat reduction sheet of this embodiment. This method is the same as the method which is disclosed in US2001-0017280A, which is hereby incorporated by reference.

As shown in FIG. 2, one favorable method for preparing the heat reduction sheet of this embodiment includes the following processes. The maintenance body 12 (that includes the porous body) having a first side 22 and a second side 24 is prepared, and the pressure impregnation of the first solution, in other words the first dope 26 is carried out on the maintenance body 12. The second solution, in other words the second dope 28, is coated on the first side 31 of the maintenance body 33 having the pressure impregnated first dope 26, and the third solution, in other words the third dope 36, is coated on the second side 32 of the maintenance body 33 having the pressure impregnated first dope 26. The three layers of the structure body 51 are formed hereby.

Here, the used dopes 26, 28, and 36, and the cooling tank 38 are the conventional types. In this embodiment, the slot die 40 to impregnate the first dope 26 is arranged on the upstream side, and the slot die 42 for coating the second dope 28 and the slot die 44 for coating the third dope 36 are arranged on the downstream side substantially facing the maintenance body. According to this, both sides of the maintenance body 33 are substantially coated at the same time.

The three layers of the formed structure body 51 are immediately cooled in the cooling tank 38 surrounding the conventional non-solvent system used for polymers immediately. The thickness of the heat reduction sheet 1, average porosity, tensile strength and the greatest compressibility and the average cavity diameter of the porous layer can be controlled by conventional methods, such as for example, changing the composition of the polymer, selecting a solvent and non-solvent, adjusting the cooling temperature, and controlling the amount of dope in the coating.

The doped 26, 28, and 36 should include a nylon polymer in the solvent system. The solvent system should include a mixture of at least one solvent and at least one non-solvent. The solvent capable of being used in cases when a nylon polymer is alcohol fusibility nylon should include a low-grade alkanol, for example, methanol, ethanol, butanol or a mixture of these. The solvent capable of being used in cases when a nylon polymer is non-alcohol fusibility nylon, should include, for example, an acid solvent, formic acid, citric acid, acetic acid, maleic acid or a similar acid. The non-solvent is selected based on the kind of solvent to be used. For example, when an acid solvent is used, the non-solvent is water, methyl formic acid, methanol and low-grade alcohol such as the ethanol, glycerol, glycol, polyol such as poly glycol, ether and ester or a mixture of these.

The maintenance body 12 having the first side 22 and the second side 24 is impregnated with the first dope 26 (slot die pressure impregnation is preferable) by various kinds of technology, for example, roll casting, spray coating (spray film), slot die coating (slot die film) and similar methods, and the first dope 26 is substantially saturated completely into the maintenance body hereby.

As used in this disclosure, the “complete saturation of the maintenance body” means that all of the fibers of the maintenance body are completely surrounded with the liquid dope, and there are no areas of the maintenance body which are not covered in liquid dope.

In one embodiment, the maintenance body 12 is maintained under the tension by this method known throughout the trade, and the first dope 26 under the stress should penetrate the maintenance body 12 and saturate it sufficiently. The maintenance body 33 impregnated with the first dope 26 is rolled, and the first dope can be pushed into the maintenance body with the roller if desired. After that, the second dope 28 is coated on the first side 31 of the maintenance body 33, and the third dope 36 is coated on the second side 32 of the maintenance body 33. The application of the second dope 28 and the third dope 36 are used substantially facing the slot dies 42 and 44 at the same time or substantially at the same time. Hereby, the mutual waterpower of the substantially facing slot die 42 and 44 supports the maintenance body 33. The slot dies 42 and 44 where the dope 28, 36 are sent under pressure bringing approximately a particularly good result for applying the second dope 28 and the third dope 36 to both sides of the maintenance body 33. In one embodiment, the slot dies 42, and 44 are arranged essentially facing each other (cf. FIG. 2), and the maintenance body 33 passes between them. The second dope 28 and the third dope 36 are coated on sides 31 and 32 with the same amount of dope. However, it is not always necessary to have the same amount of coating on sides 31 and 32.

As shown in FIG. 2, the obtained three layer structure 51 is directed to the cooling tank 38, after all of the three dopes are applied to the maintenance body 12. Cooling tank 38 is a conventional type, and includes a conventional type reservoir circulating a large quantity of non-solvents, and it is cited as the cooling tank of the dissolution polymer in which the polymer is able to be pushed into each of the structure bodies to solidify it afterwards. As a result of the cooling, the heat reduction sheet 1 is provided. After the polymer is solidified in the cooling tank, the heat reduction sheet 1 passes over the first conventional type roller in the cooling tank. The heat reduction sheet 1 passes through the cooling tank, and is routinely pulled around the second roller driven by the conventional type drive means (not illustrated). Then, the formation of the heat reduction sheet 1 is completed, however the surplus fluid from cooling tank 38 remains in there.

As shown in FIG. 2, the three layer structure 51 is submerged in the cooling tank 38. The distance between the dies 42 and 44 and the cooling tank 38, and the time it takes to reach the cooling tank 38 from the dies 42 and 44 should be as short as possible. Furthermore, after the maintenance body has been impregnated, and dope has been coated on both sides by a means such as, for example, a steam control belt, it is important to obstruct the steam from the cooling tank 38 from coming in contact with the dope, and minimizing the steam. This steam control belt prevents the dope from solidifying on the bottom of the die until the dope reaches the cooling tank 38, as well-known in this industry, and it is necessary to prevent the dope from being cooled with the steam.

As for the formed heat reduction sheet 1, the liquid overflowing from the coolant is rinsed in the conventional type first stage rinsing device. The heat reduction sheet 1 progresses over a plurality of rollers and into the washing tank 72. The washing tank 72 has water, a plurality of rollers to increase the contact time of the heat reduction sheet 1 with the water, and an appropriate SEPRO and a circulation device.

When the heat reduction sheet 1 leaves the washing tank 72, it then goes into a conventional roll-up portion, and there the heat reduction sheet 1 is rolled up on a spindle used for retention and drying.

As shown in the drawings and is clear from the above description, the dies 42 and 44 are arranged so that both surfaces of the maintenance body 33 can be coated simultaneously, and the maintenance body 33 passes therebetween perpendicularly. A controlled atmosphere controls the maintenance body that passes through a predetermined distance toward the cooling tank, and is impregnated and coated by a maintenance body substantially submerged on both sides with the dope delivered from the dies. The movement of the dies 40, 42, and 44 controls the distance, and it can be controlled easily by lowering or raising the level of the cooling fluid in the tank. Controlling this distance controls the steam belt to form the layer.

When the side moves the distance to a cooling tank once, the three layer structure 51 is submerged into the cooling fluid. The three layer structure 51 passes the predetermined distance in the cooling tank, which is well-known in this industry, before reaching the first roller.

The three layer structure 51 preferably should not match the solid or physical elements of the device in the roller or cooling stages. In other words, physical contact at the stage before solidifying in dope should preferably be avoided until there is a sufficient degree of concentration to evade and prevent the three layer structure 51 from being bent or warped which are caused in the stages after the manufacturing process.

The retention period in which the three layer structure 51 moves the cooling tank 38 is related to the movement speed of the three layer structure 51, the temperature and the density of cooling fluid, and the height of the tank. Therefore, a roller is at the bottom of the tank, which is well-known in this industry, and the direction of movement of the coated scrim is reversed, in other words, it is configured in an upward movement, from the tank to the outside.

When the heat reduction sheet 1 leaves the cooling tank 38, the cooled heat reduction sheet 1 is washed for the purpose of removing the surplus cooling fluid. The device has a first stage rinse device 70 and a washing tank 72. Heat reduction sheet 1 is wound off as well-known in this industry, and it is dried for later use afterwards.

### Electronic Device

The electronic device of the present invention includes a housing, an electronic component that generates heat (hereinafter referred to as heating electronic component) and a heat reduction sheet of the present embodiment arranged between the housing and the heating electronic component. In the electronic device of the present invention, conduction materials for radiation of heat should be placed between the heat reduction sheet and the heating electronic component and/or the heating electronic component, or sandwich the heating electronic component between the heat reduction sheet and the other side.

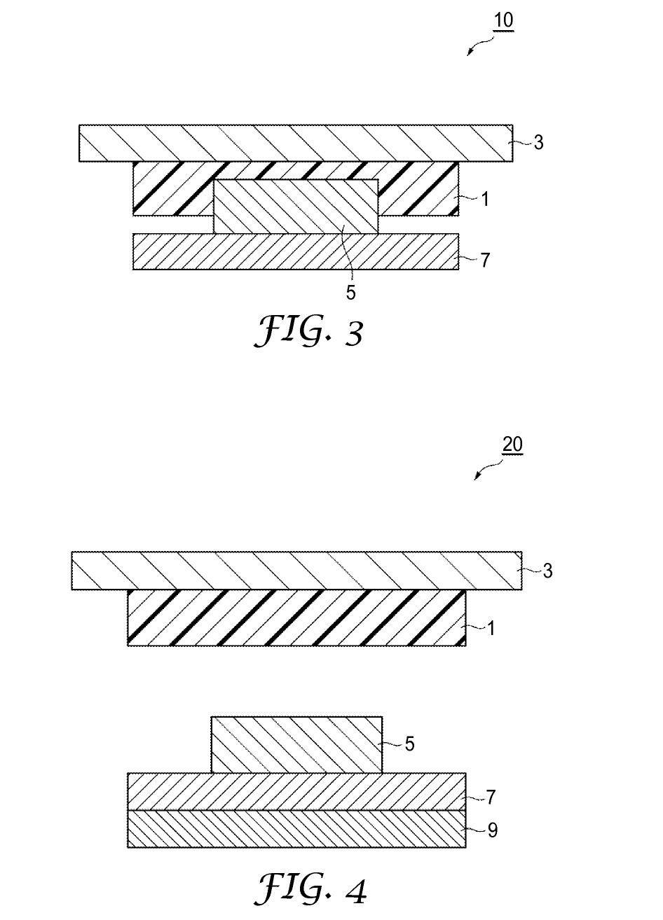

FIG. 3 is a partial diagrammatic sectional view showing one embodiment of the electronic device of the present invention. As shown in FIG. 3, the electronic device 10 has a housing (chassis) 3, a circuit board 7 having a heating electronic component 5 on the main surface, and the above described heat reduction sheet 1 placed between the housing 3 and the heating electronic component 5. In the electronic device, the gap between the housing and the electronic component is extremely small, and in this embodiment, the heat reduction sheet 1 is arranged in a form that cuts into the heating electronic component 5. Even if the above described heat reduction sheet is thin, it is excellent in heat reduction characteristics and tensile strength, and it can be applied to the extremely small gap of such an electronic device because it can be adapted to unevenness.

FIG. 4 is a partial diagrammatic sectional view showing another embodiment of the electronic device of the present invention. The electronic device 20 shown in FIG. 4 has a housing 3, a circuit board 7 having a heating electronic component 5 on the main surface, and a heat conduction material 9 layered on the surface having the heating electronic component 5 of the circuit board 7 on its opposite side. According to the electronic device 20, heat in the electronic device can effectively escape because it is equipped with heat conduction materials.

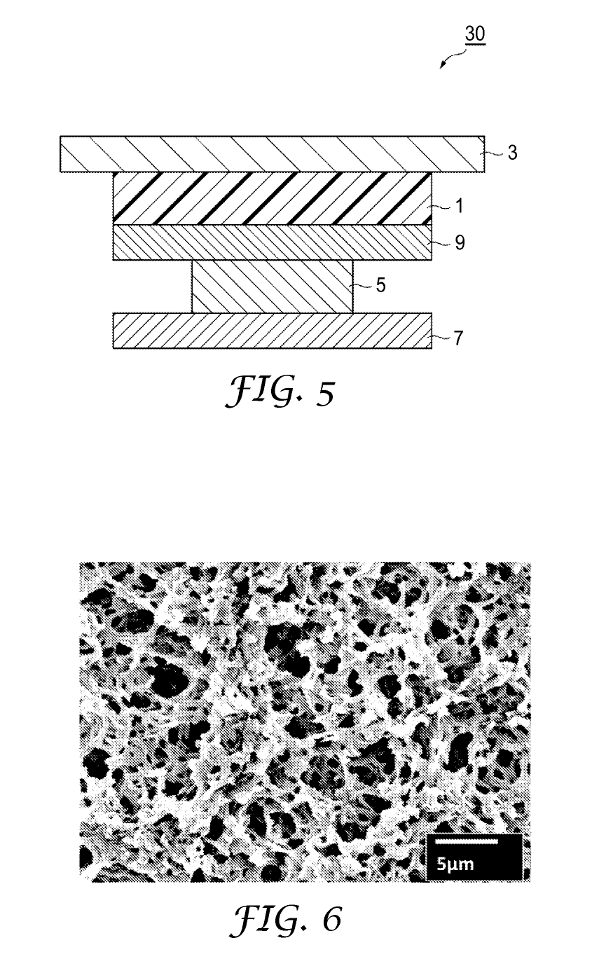

FIG. 5 is a partial diagrammatic sectional view showing yet another embodiment of the electronic device of the present invention. The electronic device 3 shown in FIG. 5 has a housing 3, a circuit board 7 having a heating electronic component 5 on the main surface, a heat conduction materials 9 arranged to contact the heating electronic component 5 and a heat reduction sheet 1 arranged between the housing 3 and the heat conduction materials. According to electronic device 30, heat in the electronic device can effectively escape because it is equipped with heat conduction materials similar to electronic device 20.

Note that, as shown in the electronic devices 20 and 30, the heat reduction sheet may be arranged between the housing 3 and the heating electronic component 5, and does not need to come in contact with the housing 3 and/or the heating electronic component 5.

Examples that can be given as the electronic devices in which the heat reduction sheet of this embodiment can be applied are sources of light such ICs, wireless modules, camera modules, batteries, and fluorescent lamps or LEDs. The mobile electronics such as cell phones, tablet PC, notebook PC, and mobile music players; display units such as a liquid crystal display, plasma display, organic electroluminescence displays, monitors, and projectors; storage devices such hard disks and SSDs; lighting devices such as incandescent lamps, fluorescent lamps, and LEDs; network machinery such as routers; image devices such as cameras and video cameras, and batteries. The heat reduction sheet of this embodiment is particularly suitable for mobile electronics such as mobile telephones and tablet PCs, in which the space between the heating electronic component and the housing is extremely small.

### EXAMPLES

The following examples are intended as illustrations only, since numerous modifications and variations within the scope of the present invention will be apparent to those skilled in the art. Unless otherwise noted, all parts, percentages, and ratios reported in the following example are on a weight basis.

### Embodiments 1-6

The fabrication of the heat reduction sheets can be found in U.S. Pat. No. 6,513,666 (Meyering, et. al.). Specific heat reduction sheets are the membrane materials used in commercially available filter cartridges. The heat reduction sheets of Embodiments 1 through 6 can be obtained as the filter membranes from filter cartridges available under the trade designation LIFEASSURE PSA (PSA010 and PSA020) and LIFEASSURE BLA (BLA010, BLA020, BLA045 and BLA065) from the 3M Purification Inc., Meriden, Conn., see Table 1. Table 1 discloses specific pore sizes of the first and second porous layers of the embodiments, as well as, thermal and mechanical properties of the heat reduction materials. Table 1 also discloses the cavity size of a Nylon 66 dope material used to impregnate the non-woven polypropylene scrim (average line diameter 30 μm, average thickness 75 μm, and an area of 30 g/m²) of the substrate.

### Comparison Example 1

A commercial polypropylene sheet having a thickness of 0.2 mm and without a cavity in the sheet was prepared.

### Comparison Example 2

A blend containing a mass ratio at 65:35 of Polypropylene, PM801A, commercial available from SunAllomer Ltd., Tokyo, Japan, having a density of 0.90 g/cm³ and melt flow index of 13.): Mineral oil, E-7, commercially available from Kaneda Corporation, was placed in an extruder and extruded, using an extrusion slot die, at a set temperature of 164° C. which is approximately 16° C. lower than the melting point of the polypropylene A one layer porous sheet was obtained by extending the obtained transparency film 30% in the cross direction and washing away the mineral oil with isopropyl alcohol.

### Comparison Example 3

A 1-layer porous sheet was obtained similar to comparison Example 2 except for that the ratio of polypropylene and mineral oil was 70:30.

### Evaluation of the Heat Reduction Sheet

The sheets of Embodiment 1-6 and Comparison Example 1-3 were evaluated as follows. The results are shown in Table 1.

### Measurement of Thermal Impedance

Test samples of 0.01 m×0.01 m (measurement area: 1.0×10⁻⁴ m², and thickness: L (m)) were cut from the heat reduction sheet made in the embodiments and comparison examples. When the test sample was placed between a heated sheet and a cooled sheet, kept under a constant load of 7.6×10⁴ N/m², and the power is increased to 4.8 W for a period of five minutes, the difference in temperatures (° C.) of the heated sheet and the cooled sheet was measured, and the thermal impedance (° C.·cm²/W) was found using the following expression.

R_{L} (° C.·cm²/W)=difference in temperature (° C.)×measurement area (cm²)/electrical power (W)

### Measurement of the Tensile Strength

Dumbbell-shaped specimen, dumbbell shape No. 3, made in accordance with JISK6251, were punched out from both the heat reduction sheets of embodiments 1-6 and the comparison examples. A tensile strength test was performed on the dumbbell-shaped specimen at an extension rate of 500 mm/min with a tensile strength tester, an Autograph AG-X 10N available from Shimadzu Corporation, Kyoto, Japan, and the tensile strength (MPa) was measured.

### Measurement of the Average Porosity

Test samples of 10 cm×10 cm were cut from the heat reduction sheet made in the embodiments and comparison examples. The volume V (cm³) and weight m (g) of these test samples were measured. These measurements were introduced into the next expression to find the average porosity (%). Porosity (volume %)={1−m/(V·d)}×100.

### Measurement of the Heated Sheet Surface Temperature (T1) and Heat Reduction Effect (ΔT)

Test samples of 0.025 m×0.025 m were cut from the heat reduction sheet made in the embodiments and comparison examples. The heated sheet was adhered to one side of this test sample, and a K thermocouple for measuring the specimen surface temperature of the other side of the test sample was set. The test sample temperature T1 when 0.4 W of power was added to the heated sheet and maintained for a period of five minutes was found using the K thermocouple. In addition, the heated sheet surface temperature T1, when there was no test sample, and when 0.4 W of power was added to the heated sheet and maintained for a period of five minutes, was measured and shown in Comparison Example 4.

The T1 in each of the embodiments and comparison example was determined from the T1 of Comparison Example 4 and the heat reduction effect A T was found.

### Measurement of the Average Cavity Diameter

The measurements were performed according to the test of ASTM-F316-70 and/or ASTM-F316-70.

### Measurement of the Maximum Compressibility

The compressibility examination was performed in accordance with JIS K7181 and the value, in which the decrease of the length of the specimen, when the specimen was destroyed, was divided by the initial specimen length, was taken as the maximum compressibility.

TABLE 1

| | Thickness | | | | | | | Average cavity | Average cavity | Max. | Cavity |
|---|---|---|---|---|---|---|---|---|---|---|---|
| | of the heat | Layer | Average | Tensile | Thermal | | | diameter of the | diameter of the | compress- | diameter of |
| | reduction | consti- | porosity | strength | Impedance | T1 | Δ T | first porous | second porous | ibility | first dope |
| No. | sheet (mm) | tution | (%)* | (Mpa) | (° C. cm²/W) | (° C.) | (° C.) | layer (μm) | layer (μm) | (%) | (μm) |
| Emb. 1 (Nylon | 0.19 | 3 layer | 48 | 10 | 8.3 | 49.2 | 5.8 | 0.1 | 0.5 | 48 | 0.1 |
| membrane for | | | | | | | | | | | |
| BLA010) | | | | | | | | | | | |
| Emb. 2 (Nylon | 0.32 | 3 layer | 88 | >15 | 15.4 | 44.2 | 10.8 | 0.1 | 5 | 88 | 0.1 |
| membrane for | | | | | | | | | | | |
| PSA010) | | | | | | | | | | | |
| Emb. 3 (Nylon | 0.19 | 3 layer | 62 | 8.3 | 10.6 | 47.6 | 7.4 | 0.2 | 2 | 62 | 0.2 |
| membrane for | | | | | | | | | | | |
| BLA020) | | | | | | | | | | | |
| Emb. 4 (Nylon | 0.19 | 3 layer | 63 | 10.5 | 12.3 | 46.4 | 8.6 | 0.45 | 6 | 63 | 0.45 |
| membrane for | | | | | | | | | | | |
| BLA045) | | | | | | | | | | | |
| Emb. 5 (Nylon | 0.2 | 3 layer | 65 | 12 | 11.0 | 47.3 | 7.7 | 0.65 | 8 | 65 | 0.65 |
| membrane for | | | | | | | | | | | |
| BLA065) | | | | | | | | | | | |
| Emb. 6 (Nylon | 0.25 | 3 layer | 54 | 4.5 | 7.3 | 49.9 | 5.1 | 0.2 | 2 | 54 | 0.2 |
| membrane for | | | | | | | | | | | |
| PSA020) | | | | | | | | | | | |

| | | | | | | | | | | |
|---|---|---|---|---|---|---|---|---|---|---|
| Comparison | 0.2 | 1 layer | 0 | >15 | 0.0 | 55 | 0 | — | — | — |
| Example 1 | | | | | | | | | | |
| Comparison | 0.11 | 1 layer | 85 | 2.7 | 5.6 | 51.1 | 3.9 | 0.8 | 85 | — |
| Example 2 | | | | | | | | | | |
| Comparison | 0.12 | 1 layer | 85 | 1.7 | 8.0 | 49.4 | 5.6 | 1.3 | 85 | — |
| Example 3 | | | | | | | | | | |

| | | | | | | | | |
|---|---|---|---|---|---|---|---|---|
| Comparison | No heat reduction sheet | — | 55 | — | — | — | — | — |
| Example 4 | | | | | | | | |

*Average porosity is a theoretical value, calculated by assuming the resin component is incompressible and air is compressible.

### Reference Example 1-5

A test was conducted to evaluate the properties of commercially available nylon mesh. (DS Econo White mesh 120 opening-15 Danier for reference example 1, 90 opening-15 Danier for reference example 2, 70 opening-15 Danier for reference example 3, 35 opening-15 Danier for reference example 4 and 50 opening-15 Danier for reference example 5. These are provided by DS Mesh Co.) The results are shown in Table 2. Note that, the commercial nylon mesh does not have a value for the maximum compressibility, since the mesh structure made it unable to be compressed.

TABLE 2

| | Thickness | | | | | | | |
|---|---|---|---|---|---|---|---|---|
| | of the heat | | Average | Tensile | Thermal | | | Size of the |
| | reduction | Layer | porosity | strength | Impedance | T1 | Δ T | hole in the |
| | sheet | constitution | (%) | (Mpa) | (° C. cm²/W) | (° C.) | (° C.) | mesh (μm) |
| Reference | 0.16 | 1 layer | 65.7 | >20 | 2.8 | 53.1 | 1.9 | 100 |
| example 1 | | | | | | | | |
| Reference | 0.22 | 1 layer | 74.5 | >20 | 4.5 | 51.9 | 3.1 | 200 |
| example 2 | | | | | | | | |
| Reference | 0.21 | 1 layer | 70.8 | >20 | 2.2 | 53.5 | 1.6 | 450 |
| example 3 | | | | | | | | |
| Reference | 0.22 | 1 layer | 83.0 | >20 | 3.9 | 52.3 | 2.7 | 650 |
| example 4 | | | | | | | | |
| Reference | 0.32 | 1 layer | 67.9 | >20 | 6.7 | 50.3 | 4.7 | 450 |
| example 5 | | | | | | | | |

As clear from Table 2, the commercial nylon mesh is excellent in tensile strength, but was insufficient with respect to its thermal impedance characteristics. In addition, the nylon fiber of the commercial nylon mesh easily came loose from the end face and was lacking in processing characteristics, and also could not be used as a heat reduction sheet. Further, the commercial nylon mesh was difficult to insert into the small space of the electronic device since it could not be compressed and was difficult to follow the unevenness.

Although the present invention has been described with reference to preferred embodiments, workers skilled in the art will recognize that changes may be made in form and detail without departing from the spirit and scope of the invention.

### REFERENCE NUMERALS

1. Heat reduction sheet
3. Housing
5. Heating electronic component
7. Circuit board
9. Heat conduction materials 10, 20, 30. Electronic devices
12. Maintenance body
14. Substrate
16. First porous layer
18. Second porous layer 26, 28,
36. Dope
33. Maintenance body impregnated with dope
38. Cooling tank
40, 42, 44. Dies
50. Device
51. Three layer structure
70. First stage rinsing device
72. Washing tank

1. A heat reduction sheet comprising:
a substrate having a first main surface and a second main surface;
a first porous layer having a first main surface, a second main surface and an average cavity diameter of between approximately 0.01 μm and approximately 10 μm; and
a second porous layer having a first main surface, a second main surface and an average cavity diameter of between approximately 0.01 μm and approximately 10 μm;
wherein at least a portion of the first main surface of the substrate is in contact with at least part of the first main surface of the first porous layer; and
wherein at least a portion of the second main surface of the substrate is in contact with at least part of the first main surface of the second porous layer.

2. The heat reduction sheet according to claim 1, wherein the substrate, the first porous layer and the second porous layer each form permeable structures.

3. The heat reduction sheet according to claim 1, wherein the heat reduction sheet has a thickness of less than approximately 0.5 mm.

4. The heat reduction sheet according to claim 1, wherein the substrate includes a non-woven fabric having an area of between approximately 5 g/m², and approximately 70 g/m².

5. A heat reduction sheet comprising:
an average porosity of more than 40% and less than 95%, a tensile strength of more than 4.0 MPa, a thickness of less than 0.5 mm and a heat reduction sheet with at least one layer; wherein the one layer is a porous layer with a cavity diameter of more than 0.01 μm and less than 10 μm.

6. The heat reduction sheet according to claim 5, wherein the greatest compressibility is more than 40% and less than 95%.

7. An electronic device comprising:
a housing;
at least one heating electronic component; and
the heat reduction sheet according to claim 1 arranged between the housing and at least one heat generating electronic component.

8. An electronic device comprising:
a housing,
an electronic component creating at least one heat, and
a heat reduction sheet provided between the housing and electronic component creating at least one heat,
wherein the heat reduction sheet further comprises:
a substrate having a first and second main surface;
a first porous layer with a first and the second main surface; and
a second porous layer with a first and the second main surface,
wherein at least a portion of the first main surface of the substrate is in contact with at least part of the first main surface of the first porous layer, and at least a portion of the second main surface of the substrate is in contact with at least part of the first main surface of the second porous layer.

9. The electronic device of claim 8, wherein at least one of the first and second porous layer has an average cavity diameter of between approximately 0.01 μm and approximately 10 μm.

10. The electronic device of claim 8,
wherein the heat reduction sheet comprises at least one porous layer with a cavity diameter of between approximately 0.01 μm and approximately 10 μm, wherein the heat reduction sheet has an average porosity of between approximately 40% and approximately 95%, a tensile strength of more than approximately 4.0 MPa and a thickness of less than approximately 0.5 mm.
